(19) United States
(12) Patent Application Publication
(10) Pub. No.: US 2026/0173474 A1
(43) Pub. Date: Jun. 18, 2026

(54) BODY CONTACT IN SOI DEVICE AND METHOD FOR FORMING THE SAME

(71) Applicant: GlobalFoundries Singapore Pte. Ltd., Singapore (SG)

(72) Inventors: Kian Ming TAN, Singapore (SG); Fangyue Liu, Singapore (SG); Rui Tze Toh, Singapore (SG)

(21) Appl. No.: 18/984,680

(22) Filed: Dec. 17, 2024

(51) Int. Cl. H10D 62/17; H10D 30/63; H10D 62/00; H10D 86/00

(52) U.S. Cl. CPC H10D 62/378; H10D 30/637; H10D 62/01; H10D 86/201

(57) ABSTRACT

A semiconductor device includes a semiconductor substrate including a buried oxide layer and a semiconductor layer over the buried oxide layer, a gate dielectric over the semiconductor layer, a gate electrode over the gate dielectric, a source region on a first side of the gate electrode, the source region including a first doped layer doped with a first type of impurities and a second doped layer above the first doped layer and doped with a second type of impurities, and a PN junction between the first doped layer and the second doped layer, a drain region on a second side of the gate electrode, a body of the semiconductor layer between the source region and the drain region, and a source silicide layer in the source region, the source silicide layer including an edge portion that contacts the first doped layer.

### BACKGROUND

In silicon on insulator (SOI) technology, metal-oxide semiconductor field-effect transistors (MOSFETs) are formed on a thin layer of silicon overlying a layer of insulating material such as silicon oxide. Devices formed on SOI offer many advantages over their bulk counterparts. For example, SOI devices generally have a reduced junction capacitance, soft-error immunity, full dielectric isolation, and little to no latch-up. SOI technology therefore enables higher speed performance, and reduced power consumption.

One of the challenges associated with SOI transistors is the floating body effect. Charge carriers generated by impact ionization near one source/drain region may accumulate in the floating body beneath a channel of the transistor. When sufficient carriers accumulate in the floating body, the body potential is effectively altered. Conventional approaches to addressing the floating body effect include so-called T-gate and I-gate (or H-gate) layouts. These approaches increase the overall gate area on a substrate, leading to both increased Cgg (gate capacitance) and reduced integration.

### SUMMARY

Embodiments of the present application relate to a semiconductor device, and in particular a transistor device, and a method for forming a semiconductor device.

In an embodiment, a semiconductor device includes a semiconductor substrate including a buried oxide layer and a semiconductor layer over the buried oxide layer, a gate dielectric over the semiconductor layer, a gate electrode over the gate dielectric, a source region on a first side of the gate electrode, the source region including a first doped layer doped with a first type of impurities and a second doped layer above the first doped layer and doped with a second type of impurities, and a PN junction between the first doped layer and the second doped layer, a drain region on a second side of the gate electrode, a body of the semiconductor layer between the source region and the drain region, and a source silicide layer in the source region, the source silicide layer including an edge portion that contacts the first doped layer.

In an embodiment, an electronic device includes a plurality of transistor structures, each transistor structure comprising a semiconductor substrate including a buried oxide layer and a semiconductor layer over the buried oxide layer, a gate dielectric over the semiconductor layer, a gate electrode over the gate dielectric, a source region on a first side of the gate electrode, the source region including a first doped layer doped with a first type of impurities and a second doped layer above the first doped layer and doped with a second type of impurities, and a PN junction between the first doped layer and the second doped layer, a drain region on a second side of the gate electrode, a body of the semiconductor layer between the source region and the drain region, and a source silicide layer in the source region, the source silicide layer including an edge portion that contacts the first doped layer.

In an embodiment, a method for forming a semiconductor device includes forming a gate dielectric over a semiconductor layer of a substrate comprising a buried oxide layer under the semiconductor layer, forming a gate electrode over the gate dielectric, forming a source region on a first side of the gate electrode, the source region including a first doped layer doped with a first type of impurities and a second doped layer above the first doped layer and doped with a second type of impurities, and a PN junction between the first doped layer and the second doped layer, forming a drain region on a second side of the gate electrode, wherein a body of the semiconductor layer is between the source region and the drain region, and forming a source silicide layer in the source region, the source silicide layer including an edge portion that contacts the first doped layer.

### BRIEF DESCRIPTION OF THE DRAWINGS

FIG. 1 illustrates an embodiment of a semiconductor device on a silicon on insulator (SOI) substrate.

FIG. 2 illustrates an embodiment of a silicidation process that may be used to form the semiconductor device of FIG. 1.

FIGS. 3A and 3B illustrate an embodiment of stages of a process of forming a semiconductor device with raised source and drain regions.

FIG. 3C illustrates a device formed by the process steps of FIGS. 3A and 3B.

FIGS. 4A to 4E illustrate another embodiment of stages of a process of forming a semiconductor device with raised source and drain regions.

FIG. 5 illustrates another embodiment of a semiconductor device on a silicon on a silicon on insulator (SOI) substrate.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and features are enlarged or diminished for visual clarity.

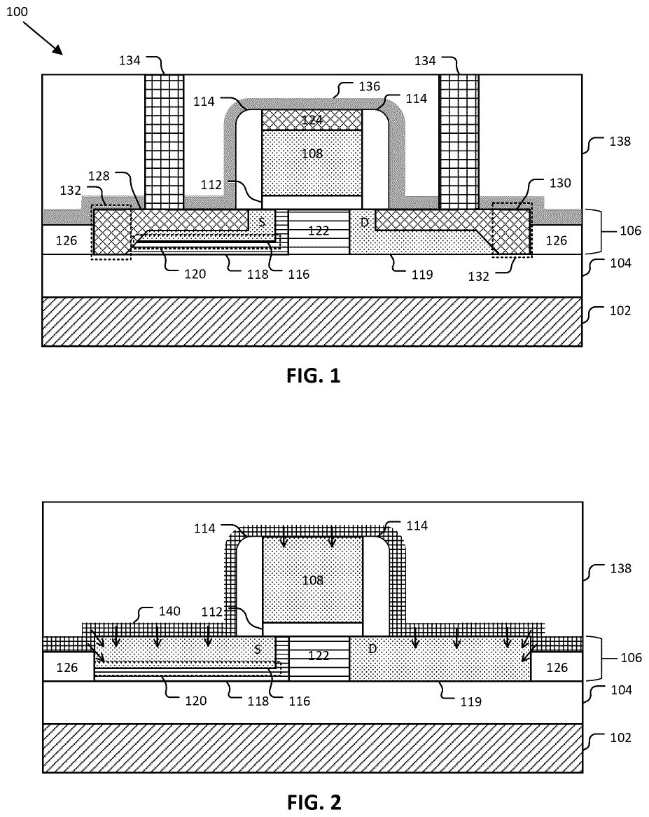

FIG. 1 illustrates an embodiment of a semiconductor device (transistor) 100 on a silicon on insulator (SOI) substrate. The SOI substrate includes a bulk semiconductor layer 102, a buried oxide (BOX) layer 104 and a semiconductor device layer 106 over the BOX layer 104. The semiconductor device layer 106 comprises a silicon material, and may comprise other materials as known in the art. For example, the material of device layer 106 may be silicon germanium material or a silicon carbide material.

A gate is located over a body 122, which is a portion of semiconductor device layer 106. A gate electrode 108 of the gate may comprise a doped polysilicon material, and a gate silicide layer 124 above the doped polysilicon. In other embodiments, the gate electrode 108 may comprise a metal material such as tungsten or titanium in addition to or instead of doped polysilicon. When the gate electrode 108 is a metal material, the silicide layer 124 may not be present.

A gate dielectric 112 is below the gate electrode 108. In various embodiments, the gate dielectric 112 may include a low-K dielectric material such as silicon oxide or a high-K dielectric material such as hafnium oxide, aluminum oxide, tantalum oxide, titanium oxide, etc., or a combination of materials.

Sidewall spacers 114 cover sidewalls of the gate electrode 108. The sidewall spacers 114 may include a dielectric material such as an oxide or nitride of silicon or a metal. In other embodiments, additional spacers such as L-shaped spacers or line-shaped spacers (not shown) may be present as known in the art.

Source region S and drain region D are located on opposite sides of gate electrode 108. The source region S includes a first doped layer 118 below a second doped layer 116, and the drain region D includes a third doped layer 119. The first doped layer 118 may be doped with a first type of impurities, and the second doped layer 116 may be doped with a second type of impurities that are different from the first type of impurities. For example, the second doped layer 116 may be doped with N-type impurities and the first doped layer 118 may be doped with P-type impurities, or vice versa. Accordingly, a PN junction 120 is present between the first and second doped layers 118/116.

The doped layer 119 of drain region D and gate electrode 108 may be doped with the first type of impurities, and the body 122 may be doped with the second type of impurities. The doping concentration of the first doped layer 118 may be higher than the doping concentration of body 122. In one example, the second doped layer 116 and doped layer 119 of drain region D have N+ doping, the first doped layer 118 has P+ doping, and the body 122 has P doping. In another example, the second doped layer 116 and doped layer 119 of drain region D have P+ doping, the first doped layer 118 has N+ doping, and the body 122 has N doping. The concentration levels of impurities of these structures may vary between embodiments (eg. the concentration profile of body 122 may or may not be uniform and could vary) and are not specifically limited.

In an embodiment, first doped layer 118 may comprise a halo implant region which extends further in the lateral plane (e.g. further under the gate) than the second doped layer 116. In other embodiments, the first and second doped layers 118 and 116 may have roughly equal widths, or the second doped layer 116 may extend further under the gate than the first doped layer 118.

The source and drain regions are bounded by shallow trench isolation (STI) structures 126 which are formed of an insulating material, e.g. silicon oxide. In some embodiments, the STI structures 126 may also include a liner material (not shown). The STI structures 126 extend to the BOX layer 104, and top surfaces of the STI structures 126 may be located below top surfaces of the source and drain regions resulting in a vertical step between the STI structures 126 and the source and drain regions. Put another way, the STI structures 126 adjacent to the source and drain regions may be recessed below a top plane of the source and drain regions. As will be explained in more detail below, the height difference between the STI structures 126 can be useful for increasing the thickness of an edge portion 132 of silicide layers over the source and drain regions. However, the height difference is not necessarily present in a fully formed device 100.

The source region includes a source silicide layer 128, and the drain region includes a drain silicide layer 130. Edge portion 132 of these silicide layers are thicker than a portion of the silicide layers which is closer to the body 122. In particular, the edge portion 132 of source silicide layer 128 extends below the PN junction 120, effectively shorting the PN junction 120 to provide a conductive path between the source silicide layer 128 and body 122 via the first doped layer 118. In the embodiment of FIG. 1, the edge portion 132 contacts the BOX layer 104. However, in other embodiments, there may be a space between the edge portion 132 and the BOX layer 104.

Contacts 134 are coupled to the source silicide layer 128 and drain silicide layer 130. The contacts 134 may include a metal material such as tungsten as well as a liner (not shown). A capping layer 136 lies over the gates, source and drain regions, and STI structures 126, and an interlayer dielectric (ILD) layer 138 is formed over the capping layer 136. The capping layer 136 may comprise a capping material such as silicon nitride, and the ILD 138 may comprise an insulating material such as a silicon oxide.

In an embodiment of the present disclosure, the source silicide layer 128 and first doped layer 118 act as a body contact for body 122. In a device without a body contact, the PN junction 120 extends across the entire source region, blocking the migration of electrons or holes between the body 122 and contact 134 of the source region. Accordingly, potential accumulates in the body 122 when current flows through the channel region. The conductive path from the body 122 through the first doped layer 118, the edge portion 132 of the source silicide layer 128 and the source contact 134 allows any accumulated charges to dissipate, returning the body to a zero bias state after current flows across the channel.

FIG. 2 illustrates an embodiment of a silicidation process that may be used to form the semiconductor device 100 of FIG. 1. The structure in FIG. 2 includes a source region comprising a first doped layer 118 and a second doped layer 116 which provide a PN junction 120 that extends to an edge of the adjacent STI structure 126. The first doped layer 118 may be formed with an angled halo implantation process so that the first doped layer 118 extends under the gate electrode 108. The second doped layer 116 may also be formed using an angled implantation process. In other embodiments, the implantation processes are not angled, and the source region does not extend as far under the gate as shown in FIG. 2.

Gate structures of the present disclosure can be manufactured in a number of ways using a number of different tools. In general, though, the methodologies and tools are used to form structures with dimensions in the micrometer and nanometer scale. The techniques employed to manufacture gate structures of the present disclosure have been adopted from integrated circuit (IC) technology. For example, the structures are built on wafers and are realized in films of material patterned by photolithographic processes on the top of a wafer.

In particular, the fabrication of the gate structures uses three basic building blocks: (i) deposition of thin films of material on a substrate, (ii) applying a patterned mask on top of the films by photolithographic imaging, and (iii) etching the films selectively to the mask. When structures are formed using a damascene process, a material may be formed over the exposed surface, and excess material is removed using a planarization process such as chemical mechanical polishing (CMP). Doped regions may be formed using an in situ doping process and/or ion implantation. These processes are known to persons of ordinary skill in the art, and may be applied as known in the art to form gate structures of the present disclosure.

The STI structures 126 are recessed below the source and drain regions. In some embodiments, the STI structures may become recessed from various cleaning, etching and polishing processes that are used to form other structures on the substrate, e.g. the various structures of the gate and/or other devices that may be present on the same substrate. While the STI structures 126 may be initially formed to have the same height as the source and drain regions, forming processes may erode the STI structures 126 so that side surfaces of the source and drain regions are exposed. In another embodiment, the STI structures 126 may be intentionally recessed to be shorter than the source and drain regions by an etching process such as a selective oxide etch. In still another embodiment, the STI structures 126 may be etched until they are completely removed, thereby exposing the entire side surfaces of the source and drain regions.

After cleaning the wafer, a metal film 140 is deposited over the top surface of the gate electrode 108, top surfaces of the source and drain regions, and the exposed edges of the source and drain regions. The metal film 140 may be a typical silicidation metal such as nickel. After deposition, an annealing process is performed which causes the metal film 140 to react with the exposed silicon as indicated by the arrows in FIG. 2. Since side surfaces of the source and drain regions are exposed by the recessed STI structures 126, an additional reaction path (e.g. a lateral path) for silicidation is available at the edges of the source and drain regions. Accordingly, the annealing causes metal film 140 on the exposed side surfaces of the source and drain region to create silicide layers in the source and drain regions in which edge portions 132 of the silicide layers are substantially thicker than portions of the silicide layers which are closer to the gate, as seen in FIG. 1.

After silicidation, an etch stop capping layer 136 is formed over the transistor, and an ILD layer 138 is formed over the capping layer 136. Source and drain contacts 134 are formed by a middle of line (MOL) process using conventional contact materials. For example, the contacts 134 may include a metal material (e.g. tungsten) and a titanium nitride barrier liner layer along the sidewalls and bottoms of the contacts. Other materials and combinations of materials are possible as known in the art. The resulting structure is shown in FIG. 1.

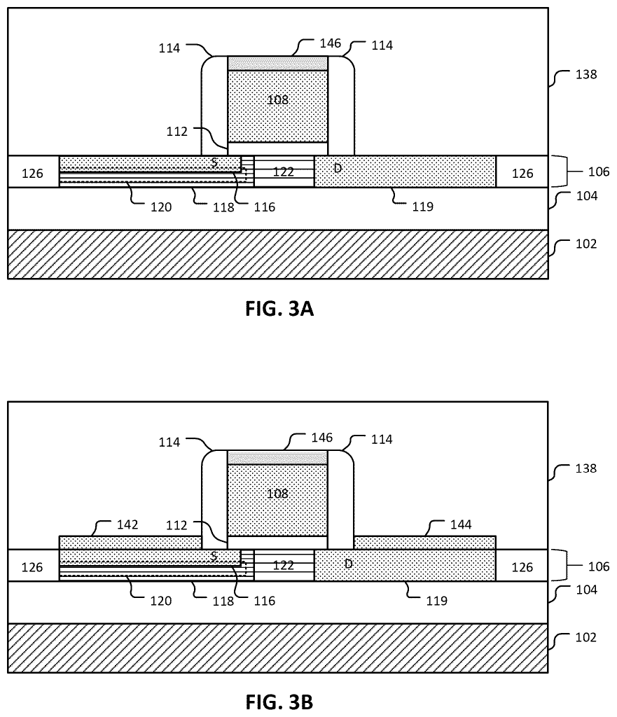

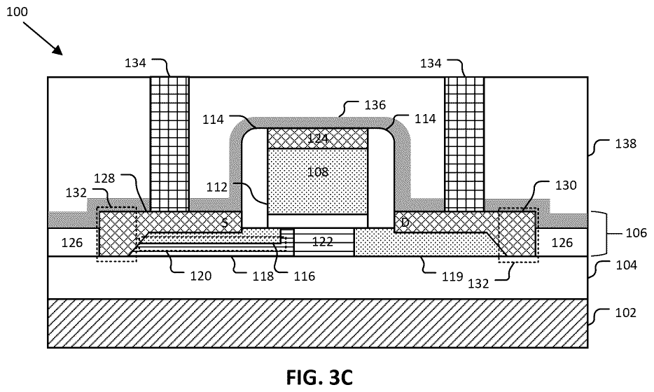

FIGS. 3A and 3B illustrate stages of a process of forming a semiconductor device 100 with raised source and drain regions according to an embodiment of the present disclosure. The structure shown in FIG. 3A may be formed using the same materials and techniques described above, except that the drain region and the second doped layer 116 are thinner, and top surfaces of STI structures 126 are coplanar with the top surface of semiconductor device layer 106. In other embodiments, the STI structures 126 may be recessed in a similar manner to the embodiment of FIG. 2 or removed completely. In addition, this embodiment includes a hard mask layer 146 that is formed over the gate electrode 108. The hard mask layer 146 may comprise an oxide or nitride material as known in the art.

In FIG. 3B, a raised source region 142 is grown over the second doped layer 116 and a raised drain region 144 is grown over the drain region D. The raised source and drain regions 142 and 144 may be formed using a typical process for forming raised source/drain (RSD) structures, e.g. an epitaxial process to grow an in situ doped crystalline silicon. In some embodiments, the raised source/drain materials may comprise various semiconductor materials, e.g. Si₁₋ₓGeₓ, Si₁₋ₓCₓ (where X=0 to 1), etc. In an embodiment in which the gate electrode 108 is a polysilicon material, the hard mask layer 146 is removed before the silicidation process is applied to form gate silicide 124. Subsequently, silicidation is performed to form a source silicide layer 128 with an edge portion 132 that extends past the PN junction 120, and remaining structures of the transistor are formed as described above, resulting in the device 100 shown in FIG. 3C.

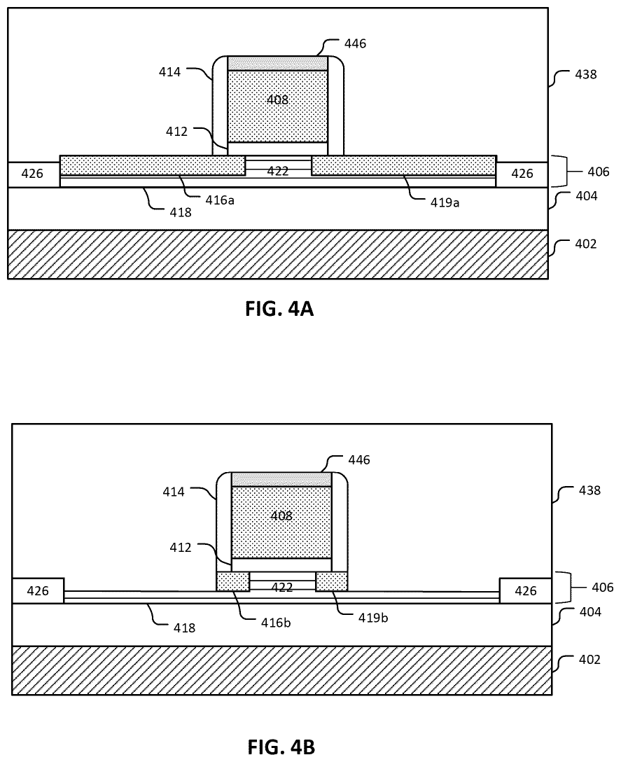

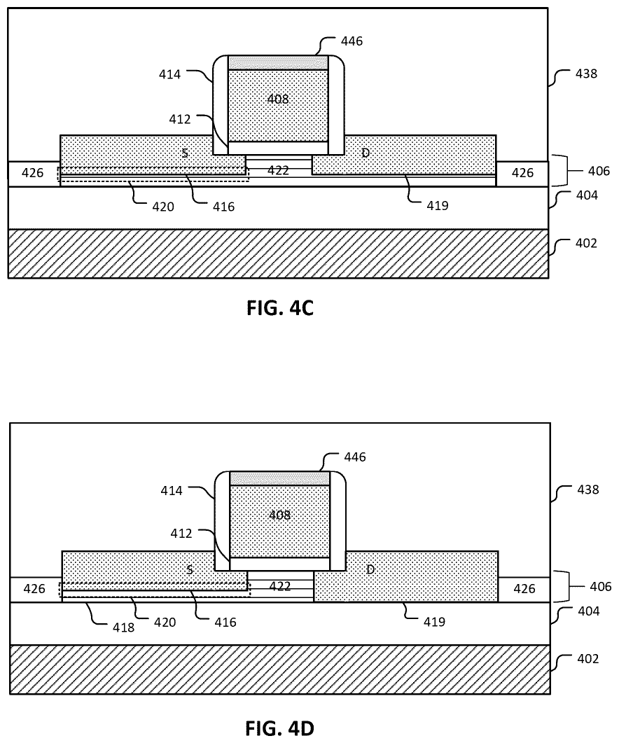

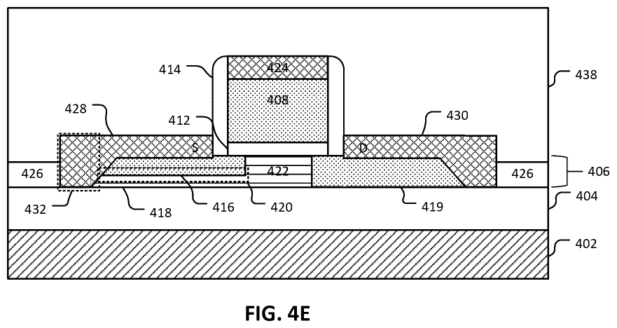

FIGS. 4A to 4E show stages of another embodiment of a process of forming a semiconductor device 100 with embedded raised source and drain regions. In the structure of FIG. 4A, an initial second doped layer 416a and an initial third doped layer 419a are formed by implanting impurities into the semiconductor device layer 406. The embodiment also includes a hard mask layer 446 that is formed over the gate electrode 408. The hard mask layer 446 may comprise an oxide or nitride material as known in the art. Next, as seen in FIG. 4B, an etching process is performed to remove portions of the initial second doped layer 416a and the initial third doped layer 419a, leaving respective portions 416b and 419b of those layers under the gate.

Raised source/drain regions may be formed with an in-situ doped epitaxial growth process as shown in FIG. 4C to form second doped layer 416 and third doped layer 419 as well as PN junction 420. In this embodiment, the PN junction 420 is formed between the second doped layer 418 and a first doped layer 416 which is above the second doped layer 418 and contiguous with body 422. In some embodiments, the raised source/drain materials may comprise various semiconductor materials, e.g. Si₁₋ₓGeₓ, Si₁₋ₓCₓ (where X=0 to 1), etc. Next, impurities are implanted at the drain side as illustrated in FIG. 4D to extend the depth of third doped layer 419. Although the implantation process is shown in FIG. 4D, the dopants could be implanted at other stages of the process such as the stage of FIG. 4A or the stage of FIG. 4B. The concentration levels of impurities and profiles of these structures may vary between embodiments and are not specifically limited.

A silicidation process is performed on the structure of FIG. 4D, resulting in the structure of FIG. 4E including a source silicide layer 428 and a drain silicide layer 430. In an embodiment in which the gate electrode 408 is a polysilicon material, the hard mask layer 446 is removed before the silicidation process is applied to form gate silicide 424. The silicidation process may be controlled to preserve a portion of PN junction 420 in the source region. The edge portion 432 of source silicide layer 428 has sufficient thickness to short the PN junction 420 and provide a conductive path to body 422. In some embodiments, the edge portion 432 may extend through the entire thickness of semiconductor device layer 406.

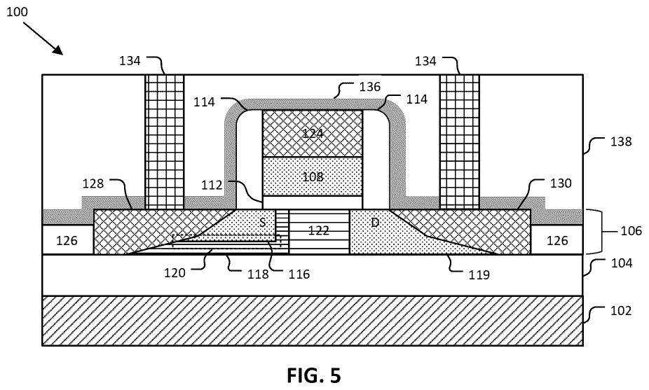

FIG. 5 shows a variation of the embodiment shown in FIG. 1. As seen in FIG. 5, the shape of source and drain silicide layers 128 and 130 may differ between embodiments. For example, the silicide material may terminate near the spacer 114 as seen in FIG. 5, or extend under the spacer 114 as seen in FIG. 1. In the embodiment of FIG. 5, the silicide layers taper as they approach the gate, and the source silicide layer 128 encroaches further into the PN junction 120 than the source silicide layer 128 of FIG. 1.

The shape of the source and drain silicide layers 128 and 130 may vary based on processing parameters of the silicidation process, materials of the source and drain regions, sizes of structures in the device 100, etc. These and other variables may be adapted to provide a device 100 with desired characteristics for a particular application. Accordingly, it should be understood that embodiments of the present disclosure are not limited to the precise shapes, sizes and proportions of the illustrative embodiments described above and shown in the figures.

Embodiments of the present disclosure provide a semiconductor device 100 in which a source silicide layer 128 extends across a PN junction 120 to provide a conductive path to a body 122 below a gate through a first (lower) doped layer 118 of the source region. Accordingly, a highly integrated transistor with a body contact can be realized with minimal processing steps. An electronic device, such as an RF device, processing device, memory device, power device, or other type of electronic device, may comprise a plurality of transistor structures, each transistor structure corresponding to a semiconductor device 100 of the present disclosure.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A semiconductor device comprising:
a semiconductor substrate including a buried oxide layer and a semiconductor layer over the buried oxide layer;
a gate dielectric over the semiconductor layer;
a gate electrode over the gate dielectric;
a source region on a first side of the gate electrode, the source region including a first doped layer doped with a first type of impurities and a second doped layer above the first doped layer and doped with a second type of impurities, and a PN junction between the first doped layer and the second doped layer;
a drain region on a second side of the gate electrode;
a body of the semiconductor layer between the source region and the drain region; and
a source silicide layer in the source region, the source silicide layer including an edge portion that contacts the first doped layer.

2. The semiconductor device of claim 1, wherein the body is doped with the first type of impurities.

3. The semiconductor device of claim 1, wherein the edge portion of the source silicide layer has a greater thickness than a portion of the source silicide layer closer to the gate electrode.

4. The semiconductor device of claim 1, wherein the edge portion of the source silicide layer contacts the buried oxide layer.

5. The semiconductor device of claim 1, wherein, the drain region is doped with the second type of impurities.

6. The semiconductor device of claim 1, further comprising a shallow trench isolation (STI) structure adjacent to the source silicide layer.

7. The semiconductor device of claim 6, wherein a top surface of the STI structure is below a top surface of the source silicide layer.

8. The semiconductor device of claim 1, further comprising a drain silicide layer in the drain region, the drain silicide layer having an edge portion with a greater thickness than a portion of the drain silicide layer closer to the gate electrode.

9. The semiconductor device of claim 1, wherein at least a portion of the source region is raised above the semiconductor layer of the semiconductor substrate.

10. The semiconductor device of claim 9, wherein at least a portion of the drain region is raised above the semiconductor layer of the semiconductor substrate.

11. The semiconductor device of claim 1, further comprising a source contact, wherein the source silicide layer provides a conductive path between the source contact, the first doped layer and the body.

12. An electronic device comprising a plurality of transistor structures, each transistor structure comprising:
a semiconductor substrate including a buried oxide layer and a semiconductor layer over the buried oxide layer;
a gate dielectric over the semiconductor layer;
a gate electrode over the gate dielectric;
a source region on a first side of the gate electrode, the source region including a first doped layer doped with a first type of impurities and a second doped layer above the first doped layer and doped with a second type of impurities, and a PN junction between the first doped layer and the second doped layer;
a drain region on a second side of the gate electrode;
a body of the semiconductor layer between the source region and the drain region; and
a source silicide layer in the source region, the source silicide layer including an edge portion that contacts the first doped layer.

13. The transistor structure of claim 12, wherein the body is doped with the first type of impurities.

14. The transistor structure of claim 12, wherein the edge portion of the source silicide layer has a greater thickness than a portion of the source silicide layer closer to the gate electrode.

15. The transistor structure of claim 12, wherein the edge portion of the source silicide layer contacts the buried oxide layer.

16. The transistor structure of claim 12, further comprising a shallow trench isolation (STI) structure adjacent to the source silicide layer.

17. The transistor structure of claim 16, wherein a top surface of the STI structure is below a top surface of the source silicide layer.

18. The transistor structure of claim 12, wherein at least a portion of the source region is raised above the semiconductor layer of the semiconductor substrate.

19. The transistor structure of claim 12, further comprising a source contact, wherein the source silicide layer provides a conductive path between the source contact, the first doped layer and the body.

20. A method of forming a semiconductor device, the method comprising:
forming a gate dielectric over a semiconductor layer of a substrate comprising a buried oxide layer under the semiconductor layer;
forming a gate electrode over the gate dielectric;
forming a source region on a first side of the gate electrode, the source region including a first doped layer doped with a first type of impurities and a second doped layer above the first doped layer and doped with a second type of impurities, and a PN junction between the first doped layer and the second doped layer;
forming a drain region on a second side of the gate electrode, wherein a body of the semiconductor layer is between the source region and the drain region; and
forming a source silicide layer in the source region, the source silicide layer including an edge portion that contacts the first doped layer.
